(19) United States
(12) Patent Application Publication
(10) Pub. No.: US 2008/0018242 A1
(43) Pub. Date: Jan. 24, 2008

(54) DOUBLE SIDE EMITTING ORGANIC LIGHT EMITTING DIODE AND METHOD OF FABRICATING THE SAME

(75) Inventors: Wen-Jian Shen, Taoyuan County (TW); Chih-Kwang Tzen, Pingtung County (TW); Cheng-Feng Su, Taipei County (TW); Shuenn-Jiun Tang, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: CHUNGHWA PICTURE TUBES, LTD., Taipei (TW)

(21) Appl. No.: 11/459,005

(22) Filed: Jul. 20, 2006

(51) Int. Cl. H05B 33/00; H01J 1/62

(52) U.S. Cl. 313/506; 313/504

(57) ABSTRACT

A method of fabricating a double side emitting organic light emitting diode (OLED) including the following steps is provided. First, a transparent substrate is provided. Then, a first transparent electrode and an organic light emitting layer are sequentially formed on the transparent substrate. Next, a second transparent electrode is formed on the organic light emitting layer. The method of forming the second transparent electrode includes the following steps. A first film composed of alkali metal compound or alkaline-earth metal compound is formed on the organic light emitting layer; a second film composed of metal material is formed on the first film and has a thickness between 20 angstroms and 50 angstroms; a third film composed of transparent conductive material is formed on the second film by using a plasma diffusion deposition process or an ionic thermal evaporation process.

### BACKGROUND OF THE INVENTION

1. Field of the Invention

The present invention generally relates to an organic light emitting diode (OLED) and a method of fabricating the same, and more particularly, to a double side emitting OLED having a better electrode transmission and a lower driving voltage and a method of fabricating the same.

2. Description of Related Art

An organic electroluminescent device is a semiconductor device in which electrical power is converted into optical power with a high conversion rate. An organic light emitting diode is commonly used as an indicator, a display panel and an optical pick-up light-emitting device. Further, the organic light emitting diode comprises special characteristics, such as wide viewing angle, simple processing, low cost, quick response time, wide operating temperature and full color, the display characteristics demanded by the multi-media era can be accommodated. The research on organic light emitting diode thus becomes a very popular topic in recent years.

The basic structure of an organic light emitting diode (OLED) includes a glass substrate, a metal electrode, a transparent electrode and an organic electroluminescent (OEL) layer. The optical emission mechanism behind an organic light emitting diode is based upon the radiative recombination of a trapped charge. Specifically, the metal electrode and the transparent electrode serve as the cathode and the anode, respectively. As a forward bias is applied between the two electrodes, electrons and holes from the metal electrode and the transparent electrode, respectively, are injected into a luminescent layer. When the injected holes and the injected electrons are recombined, a photon is formed by radiative recombination and a light emission effect is resulted.

FIGS. 1A and 1B are schematic cross-sectional views showing a conventional bottom emission OLED and a conventional top emission OLED, respectively. First, referring to FIG. 1A, a conventional bottom emission OLED 100 mainly includes a transparent substrate 110, a transparent electrode 120, an OEL layer 130 and a metal electrode 140. The transparent electrode 120 is disposed on the transparent substrate 110 to serve as an anode of the OLED. The OEL layer 130 is disposed on the transparent electrode 120 to serve as a light emitting layer. The metal electrode 140 disposed on the OEL layer 130 serves as a cathode of the OLED. When a voltage difference is applied between the transparent electrode 120 and the metal electrode 140, a light 150 emitted from the OEL layer 130 travels toward the outside of the OLED 100 through the transparent electrode 120 and the transparent substrate 110 and exits from the bottom of the OLED 100.

On the contrary, the top emission OLED 100′ as shown in FIG. 1B is to form a metal electrode 140′ on the transparent substrate 110. Then, the OEL layer 130′ and the transparent electrode 120′ are sequentially formed on the metal electrode 140′. Similarly, as a voltage difference is applied between the metal electrode 140′ and the transparent electrode 120′, a light 150′ emitted from the OEL layer 130 travels toward the outside of the OLED 100 through the transparent electrode 120′ and exits from the top of the OLED 100′.

Although the above-mentioned bottom emission OLED or top emission OLED may satisfy the application of a single side emitting OLED, a double side emitting OLED display, however, can fulfil the market requirement broadly.

Generally speaking, a top electrode of a current double side emitting OLED is formed by the physical vapour deposition (PVD) process. However, high energy argon ions and oxygen ions would be generated during the generation of plasma. These high energy argon ions and oxygen ions may collide with a surface of the OEL layer and cause ion bombardment, which further affects the luminescence efficiency and driving voltage of the OLED.

For the double side emitting OLED, the transmission of the top and bottom transparent electrodes and the driving voltage are the main reasons which affect the applications of the OLED. Accordingly, how to fabricate a double side emitting OLED having a better electrode transmission and a lower driving voltage is an important issue in the current OLED display technology.

### SUMMARY OF THE INVENTION

Accordingly, the present invention is directed to a method of fabricating a double side emitting OLED to solve the problem of poor transmission of the transparent electrode of the conventional double side emitting OLED.

The present invention is also directed to a double side emitting OLED having a lower driving voltage.

As embodied and broadly described herein, the present invention provides a method of fabricating a double side emitting organic light emitting diode. First, a transparent substrate is provided. Then, a first transparent electrode and an organic electroluminescent layer are sequentially formed on the transparent substrate. Next, a second transparent electrode is formed on the organic electroluminescent layer. The method of forming the second transparent electrode comprises the following steps. A first film is formed on the organic electroluminescent layer, wherein the first film is made of alkali metal compound or alkaline-earth metal compound. Then, a second film is formed on the first film, wherein the second film is made of a metallic material, F and a thickness of the second film is between 20 angstroms and 50 angstroms. Finally, a plasma diffusion deposition process or an ion thermal evaporation process is performed to form a third film on the second film, wherein the third film is made of a transparent conductive material.

According to an embodiment of the present invention, the transparent substrate comprises a glass substrate.

According to an embodiment of the present invention, the material of the first transparent electrode is selected from the group consisting of indium tin oxide, indium zinc oxide, aluminium zinc oxide, antimony tin oxide, zinc oxide, indium oxide and tin oxide.

According to an embodiment of the present invention, the method of forming the organic electroluminescent layer comprises the following steps. First, a hole injection layer is formed on the first transparent electrode. Next, a hole transport layer is formed on the hole injection layer. Then, a light emitting layer is formed on the hole transport layer. An electron transport layer is formed on the light emitting layer. Finally, an electron injection layer is formed on the electron transport layer.

According to an embodiment of the present invention, the thickness of the first film is between 5 angstroms and 100 angstroms.

According to an embodiment of the present invention, the alkaline metal compound comprises a lithium compound.

According to an embodiment of the present invention, the lithium compound is selected from the group consisting of lithium fluoride and lithium oxide.

According to an embodiment of the present invention, the metallic material is selected from the group consisting of Al, Au, Ag, Ca, Mg, Mg/Al alloy and Mg/Ag alloy.

According to an embodiment of the present invention, the thickness of the third film is between 500 angstroms and 3000 angstroms.

According to an embodiment of the present invention, the plasma power of the plasma diffusion deposition process is between 5000W and 15000W.

According to an embodiment of the present invention, the operation temperature of the plasma diffusion deposition process is between 20° C. and 300° C.

According to an embodiment of the present invention, the plasma gas used in the plasma diffusion deposition process comprises Ar, O₂, N₂ or water vapor.

According to an embodiment of the present invention, the transparent conductive material comprises indium tin oxide or indium zinc oxide.

As embodied and broadly described herein, the present invention also provides a double side emitting organic light emitting diode. The double side emitting organic light emitting diode mainly comprises a transparent substrate, a first transparent electrode, an organic electroluminescent layer and a second transparent electrode. The first transparent electrode is disposed on the transparent substrate. The organic electroluminescent layer is disposed on the first transparent electrode. The second transparent electrode is disposed on the organic electroluminescent layer, and comprises a first film, a second film and a third film. The first film is disposed on the organic electroluminescent layer, and is made of an alkaline metal compound or alkaline-earth metal compound. The second film is disposed on the first film, and is made of a metallic material. A thickness of the second film is between 20 angstroms and 50 angstroms. The third film is disposed on the second film, and is made of a transparent conductive material. The driving voltage of the double side emitting organic light emitting diode is smaller than or equal to 5 volt, and the transmission rate of the second transparent electrode is higher than 50%.

According to an embodiment of the present invention, the transparent substrate comprises a glass substrate.

According to an embodiment of the present invention, the material of the first transparent electrode is selected from the group consisting of indium tin oxide, indium zinc oxide, aluminium zinc oxide, antimony tin oxide, zinc oxide, indium oxide and tin oxide.

According to an embodiment of the present invention, the organic electroluminescent layer comprises a hole injection layer, a hole transport layer, a light emitting layer, an electron transport layer and an electron injection layer. The hole injection layer is disposed on the first transparent electrode. The hole transport layer is disposed on the hole injection layer. The light emitting layer is disposed on the hole transport layer. The electron transport layer is disposed on the light emitting layer. The electron injection layer is disposed on the electron transport layer.

According to an embodiment of the present invention, the thickness of the first film is between 5 angstroms and 100 angstroms.

According to an embodiment of the present invention, the alkaline metal compound comprises a lithium compound.

According to an embodiment of the present invention, the lithium compound is selected from the group consisting of lithium fluoride and lithium oxide.

According to an embodiment of the present invention, the metallic material is selected from the group consisting of Al, Au, Ag, Ca, Mg, Mg/Al alloy and Mg/Ag alloy.

According to an embodiment of the present invention, the thickness of the third film is between 500 angstroms and 3000 angstroms.

According to an embodiment of the present invention, the transparent conductive material comprises indium tin oxide or indium zinc oxide.

The present invention utilizes the plasma diffusion deposition process or the ionic thermal evaporation process to form the third film (the transparent conductive layer) on the second film (the thin metallic layer). Since the effect of ion bombardment during the plasma diffusion deposition process is lower, therefore, the OLED fabricated according to the above-mentioned processes has a lower driving voltage. More specifically, if the thickness of the second film is controlled between 20 angstroms and 50 angstroms, the transmission rate of the transparent electrode may be higher than 50% and the driving voltage of the OLED smaller than or equal to 5 volt. As a result, the transmission of the electrode of the double side emitting OLED fabricated according to the above-mentioned processes is higher, and the driving voltage thereof is lower.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A and 1B are schematic cross-sectional views showing a conventional bottom emission OLED and a conventional top emission OLED, respectively.

FIGS. 2A to 2C are schematic, cross-sectional diagrams illustrating the process flow for fabricating a double side emitting OLED according to a preferred embodiment of the present invention.

FIG. 3 is a schematic view showing a plasma diffusion deposition system.

FIG. 4 is a diagram illustrating a relationship between the thickness of the second film, the driving voltage and the transmission of the transparent electrode measured according to the devices having the stacked structure of CuPc/NPB/Alq3/Alq3 with the different transparent electrode (the second film of the transparent electrode has different thickness) of the present invention.

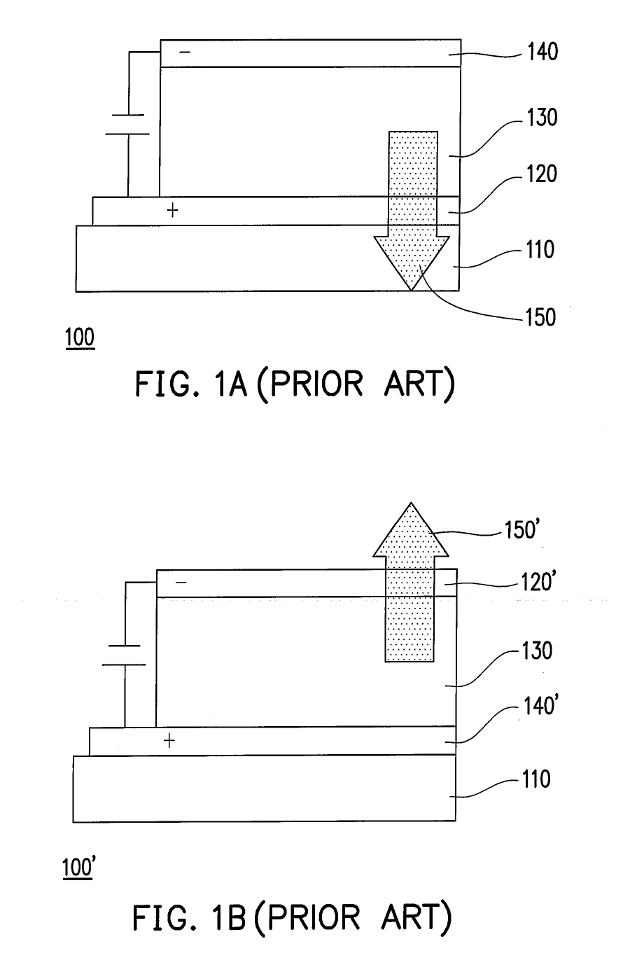

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

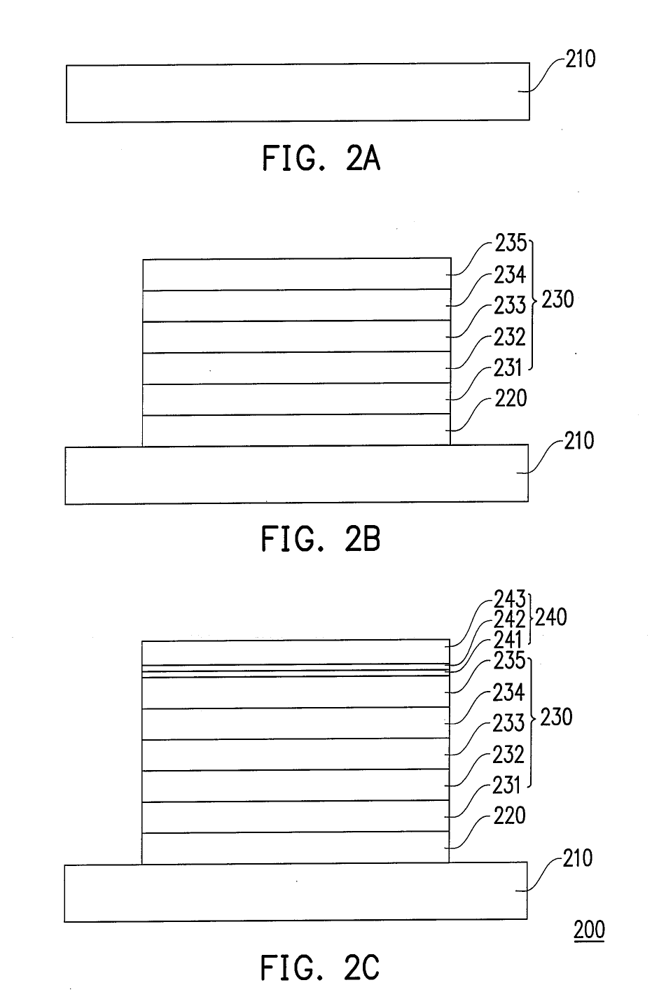

FIGS. 2A to 2C are schematic, cross-sectional diagrams illustrating the process flow for fabricating a double side emitting OLED according to a preferred embodiment of the present invention. First, referring to FIG. 2A, a transparent substrate 210 is provided. In one embodiment of the present invention, the transparent substrate 210 may be a glass substrate or a substrate made of other suitable transparent material. Next, referring to FIG. 2B, a first transparent electrode 220 and an OEL layer 230 are sequentially formed on the transparent substrate 210. Generally speaking, a material of the first transparent electrode 220 is selected from the group consisting of indium tin oxide, indium zinc oxide, aluminium zinc oxide, antimony tin oxide, zinc oxide, indium oxide and tin oxide. Besides, in one embodiment of the present invention, the method of fabricating the OEL layer 230 comprises the following steps. First, a hole injection layer 231 is formed on the first transparent electrode 220. Next, a hole transport layer 232 is formed on the hole injection layer 231. Then, a light emitting layer 233 is formed on the hole transport layer 232. Next, an electron transport layer 234 is formed on the light emitting layer 233. Finally, an electron injection layer 235 is formed on the electron transport layer 234. The fabrication of the OEL layer 230 is completed by the above processes. It should be noted that the OEL layer 230 may only comprise any one, any two, any three or any four of the layers except the five-layer structure. The type and the number of the films which the OEL layer 230 comprises are not limited in the present invention.

Next, referring to FIG. 2C, a second transparent electrode 240 is formed on the OEL layer 230. The second transparent electrode 240 of the present invention is composed of a first film 241, a second film 242 and a third film 243. First, a first film 241 is formed on the OEL layer 230 and is made of a lithium compound, such as lithium fluoride, lithium oxide and the like. The thickness of the first film 241 is between 5 angstroms and 100 angstroms. In this embodiment, the first film 241 is made of lithium fluoride. Next, the second film 242 is formed on the first film 241. The second film 242 is a thin metallic film, and the thin metallic film may be made of Al, Au, Ag, Ca, Mg, Mg/Al alloy, Mg/Ag alloy and the like. The transmission of the second transparent electrode 240 depends on the thickness of the second film 242, and therefore the transmission of the second transparent electrode 240 may be adjusted according to the thickness of the second film 242. In one embodiment of the present invention, a preferred thickness of the second film 242 is between 20 angstroms and 50 angstroms. Besides, the first film 241 and the second film 242 may be formed by sputtering, thermal evaporation, physical vapour deposition or other process.

Finally, a plasma diffusion deposition process or an ionic thermal evaporation process is performed to form a third film 243 on the second film 242, wherein the third film 243 is made of a transparent conductive material, such as indium tin oxide, indium zinc oxide and the like. The thickness of the third film is between 500 angstroms and 3000 angstroms. Thus far, the double side emitting OLED 200 is formed according to the above processes.

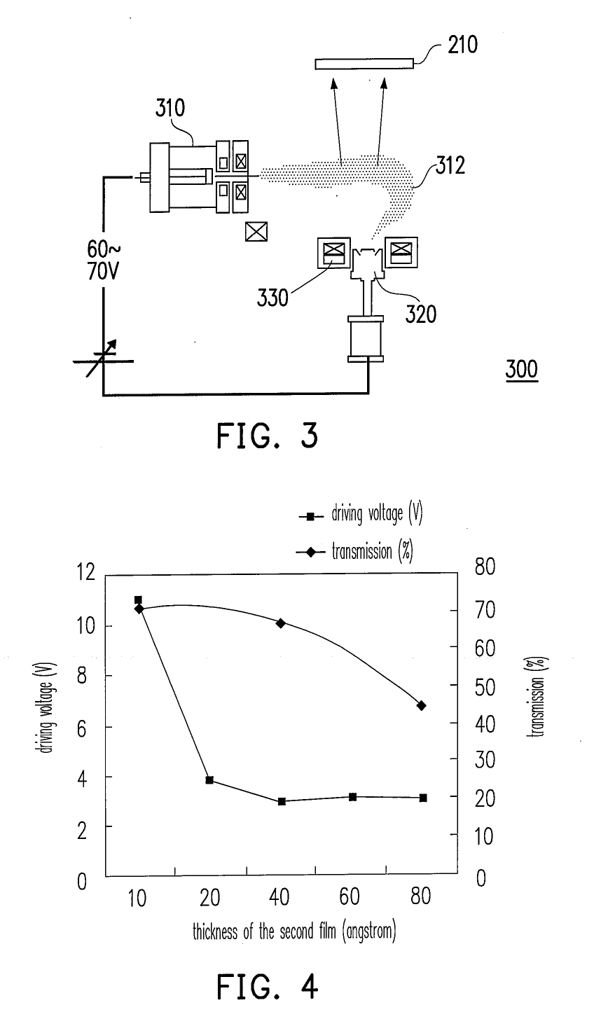

FIG. 3 is a schematic view showing a plasma diffusion deposition system (PDDS). Referring to FIG. 3, the plasma diffusion deposition system 300 mainly comprises a plasma gun 310, a target 320 and a plasma beam controller 330. The substrate 210 to be deposited is disposed right above the target 320. Besides, in the embodiment, the target 320 is made of indium tin oxide. The plasma 312 generated from the plasma gun 310 is controlled by the plasma beam controller 330, such that the plasma 312 is turned toward the target 320 for heating the target 320. The target 320 may evaporate after heated and then be deposited on the substrate 210 to form the indium tin oxide layer.

In one embodiment of the present invention, the plasma gas used in the plasma diffusion deposition comprises Ar, O₂, N₂ or water vapor. Besides, the plasma power of the plasma diffusion deposition process is between 5000W and 15000W, and the operation temperature of the plasma diffusion deposition process is between 20° C. and 300° C. Since the plasma diffusion deposition process may reduce the effect of ion bombardment, the double side emitting OLED 200 formed according to the above processes may have a lower driving voltage.

To prove that the double side emitting OLED 200 formed according to the above processes has a higher electrode transmission and a lower driving voltage, the present invention fabricates devices having a stacked structure of CuPc (200 angstroms)/NPB (500 angstroms)/Alq3 (350 angstroms)/Alq3 (150 angstroms) with the different transparent electrode (the second film of the transparent electrode has a different thickness) and measures the driving voltage of the devices and the transmission of the transparent electrode to obtain a relationship between the thickness of the second film, the driving voltage of the devices and the transmission of the transparent electrode. It is clear that from FIG. 4, when the thickness of the second film is between 20 angstroms and 50 angstroms, the transmission of the transparent electrode is larger than 50% and the driving voltage of the device is lower than or equal to 5 volt. Accordingly, the requirements of a higher transmission of the transparent electrode and a lower driving voltage are achieved.

In summary, the transparent electrode of the double side emitting OLED of the present invention comprises three films—the first film made of the lithium compound (such as lithium fluoride);the second film made of the metallic material (such as aluminium); the third film made of the transparent conductive material (such as indium tin oxide). The present invention features that the third film disposed on the second film is formed by the plasma diffusion deposition process or ionic thermal evaporation process. Since the effect of ion bombardment generated during the plasma diffusion deposition process is lower, therefore, the OLED formed according to the processes has a lower driving voltage. From the experiment data shown in FIG. 4, as the thickness of the second film is between 20 angstroms and 50 angstroms, the transmission rate of the transparent electrode is larger than 50% and the driving voltage of the device is lower than or equal to 5 volt. Accordingly, the double side emitting OLED of the present invention has a higher transmission rate of the transparent electrode and a lower driving voltage.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a double side emitting organic light emitting diode, comprising:
providing a transparent substrate;
forming a first transparent electrode and an organic electroluminescent layer on the transparent substrate sequentially;
forming a second transparent electrode on the organic electroluminescent layer, wherein the step of forming the second transparent electrode comprises:
forming a first film on the organic electroluminescent layer, wherein the first film is made of an alkali metal compound or an alkaline-earth metal compound;
forming a second film on the first film, wherein the second film is made of a metallic material, and a thickness of the second film is between 20 angstroms and 50 angstroms; and
performing a plasma diffusion deposition process or an ionic thermal evaporation process to form a third film on the second film, wherein the third film is made of a transparent conductive material.

2. The method of fabricating a double side emitting organic light emitting diode according to claim 1, wherein the transparent substrate comprises a glass substrate.

3. The method of fabricating a double side emitting organic light emitting diode according to claim 1, wherein a material of the first transparent electrode is selected from a group consisting of indium tin oxide, indium zinc oxide, aluminiun zinc oxide, antimony tin oxide, zinc oxide, indium oxide and tin oxide.

4. The method of fabricating a double side emitting organic light emitting diode according to claim 1, wherein the step of forming the organic electroluminescent layer comprises:
forming a hole injection layer on the first transparent electrode;
forming a hole transport layer on the hole injection layer;
forming a light emitting layer on the hole transport layer;
forming an electron transport layer on the light emitting layer; and
forming an electron injection layer on the electron transport layer.

5. The method of fabricating a double side emitting organic light emitting diode according to claim 1, wherein a thickness of the first film is between 5 angstroms and 100 angstroms.

6. The method of fabricating a double side emitting organic light emitting diode according to claim 1, wherein the alkali metal compound comprises a lithium compound.

7. The method of fabricating a double side emitting organic light emitting diode according to claim 6, wherein the lithium compound is selected from a group consisting of lithium fluoride and lithium oxide.

8. The method of fabricating a double side emitting organic light emitting diode according to claim 1, wherein the metallic material is selected from a group consisting of Al, Au, Ag, Ca, Mg, Mg/Al alloy and Mg/Ag alloy.

9. The method of fabricating a double side emitting organic light emitting diode according to claim 1, wherein a thickness of the third film is between 500 angstroms and 3000 angstroms.

10. The method of fabricating a double side emitting organic light emitting diode according to claim 1, wherein a plasma power of the plasma diffusion deposition process is between 5000W and 15000W.

11. The method of fabricating a double side emitting organic light emitting diode according to claim 1, wherein an operation temperature of the plasma diffusion deposition process is between 20° C. and 300° C.

12. The method of fabricating a double side emitting organic light emitting diode according to claim 1, wherein a plasma gas used in the plasma diffusion deposition process comprises Ar, O₂, N₂ or water vapor.

13. The method of fabricating a double side emitting organic light emitting diode according to claim 1, wherein the transparent conductive material comprises indium tin oxide or indium zinc oxide.

14. A double side emitting organic light emitting diode, comprising:
a transparent substrate;
a first transparent electrode, disposed on the transparent substrate;
an organic electroluminescent layer, disposed on the first transparent electrode; and
a second transparent electrode, disposed on the organic electroluminescent layer, wherein the second transparent electrode comprises:
a first film, disposed on the organic electroluminescent layer, wherein the first film is made of an alkali metal compound or an alkaline-earth metal compound;
a second film, disposed on the first film, wherein the second film is made of a metallic material, and a thickness of the second film is between 20 angstroms and 50 angstroms; and
a third film, disposed on the second film, wherein the third film is made of a transparent conductive material;
wherein, a driving voltage of the double side emitting organic light emitting diode is smaller than or equal to 5 volt, and a transmission rate of the second transparent electrode is higher than 50%.

15. The double side emitting organic light emitting diode according to claim 14, wherein the transparent substrate comprises a glass substrate.

16. The double side emitting organic light emitting diode according to claim 14, wherein a material of the first transparent electrode is selected from a group consisting of indium tin oxide, indium zinc oxide, aluminium zinc oxide, antimony tin oxide, zinc oxide, indium oxide and tin oxide.

17. The double side emitting organic light emitting diode according to claim 14, wherein the organic electroluminescent layer comprises:
a hole injection layer, disposed on the first transparent electrode;
a hole transport layer, disposed on the hole injection layer;
a light emitting layer, disposed on the hole transport layer;
an electron transport layer, disposed on the light emitting layer; and
an electron injection layer, disposed on the electron transport layer.

18. The double side emitting organic light emitting diode according to claim 14, wherein a thickness of the first film is between 5 angstroms and 100 angstroms.

19. The double side emitting organic light emitting diode according to claim 14, wherein the alkali metal compound comprises a lithium compound.

20. The double side emitting organic light emitting diode according to claim 19, wherein the lithium compound is selected from a group consisting of lithium fluoride and lithium oxide.

21. The double side emitting organic light emitting diode according to claim 14, wherein the metallic material is selected from a group consisting of Al, Au, Ag, Ca, Mg, Mg/Al alloy and Mg/Ag alloy.

22. The double side emitting organic light emitting diode according to claim 13, wherein a thickness of the third film is between 500 angstroms and 3000 angstroms.

23. The double side emitting organic light emitting diode according to claim 13, wherein the transparent conductive material comprises indium tin oxide or indium zinc oxide.
